(19) United States
(12) Patent Application Publication
(10) Pub. No.: US 2015/0325709 A1
(43) Pub. Date: Nov. 12, 2015

(54) SEMICONDUCTOR DEVICE

(71) Applicant: TOYOTA JIDOSHA KABUSHIKI KAISHA, Toyota-shi (JP)

(72) Inventors: Takahiro ITO, Nagakute-shi (JP); Toru ONISHI, Nagoya-shi (JP); Hideya YAMADERA, Nagakute-shi (JP); Satoru MACHIDA, Nagakute-shi (JP); Yusuke YAMASHITA, Nagakute-shi (JP)

(21) Appl. No.: 14/657,289

(22) Filed: Mar. 13, 2015

(30) Foreign Application Priority Data
May 9, 2014 (JP) 2014-097509

(51) Int. Cl. H01L 29/872; H01L 29/16; H01L 29/06; H01L 29/47

(52) U.S. Cl. CPC H01L 29/872; H01L 29/47; H01L 29/16; H01L 29/06

(57) ABSTRACT

A semiconductor device is provided with a semiconductor layer including Si and a Schottky electrode being in Schottky contact with at least a part of one of main surfaces of the semiconductor layer. A material of the Schottky electrode is a Al—Si alloy including at least one metal selected from the group consisting of Ti, Ta, Nb, Hf, Zr, W, Mo and V.

### CROSS-REFERENCE TO RELATED APPLICATION

This application claims priority to Japanese Patent Application No. 2014-097509 filed on May 9, 2014, the contents of which are hereby incorporated by reference into the present application.

### TECHNICAL FIELD

The technique disclosed in the present application relates to a semiconductor device including a Schottky electrode.

### DESCRIPTION OF RELATED ART

A semiconductor device demonstrating a specific function is formed, using a barrier height between a semiconductor layer and a Schottky electrode. For example, a Schottky diode demonstrating a rectification action is formed, using the barrier height between the semiconductor layer and the Schottky electrode.

Japanese Patent Application Publication Nos. 1996-45874, 2001-7351, 2001-135814, and 2003-92416 disclose the Schottky electrode in Schottky contact with the semiconductor layer including Si. These patent documents propose use of an Al—Si alloy as a material of the Schottky electrode. The Schottky electrode of the Al—Si alloy suppresses diffusion of Al included in the electrode to the semiconductor layer and suppresses generation of aluminum spikes.

### BRIEF SUMMARY OF INVENTION

In a process of forming the Schottky electrode of the Al—Si alloy on a surface of the semiconductor layer, for example, a heat treatment of 500° C. in a reducing atmosphere is required to lower interface resistance between the semiconductor layer and the Schottky electrode. When such a heat treatment is applied, Al included in the Schottky electrode of the Al—Si alloy diffuses to an interface between the semiconductor layer and the Schottky electrode, resulting in segregation of Si and generation of Si nodule. To lower the interface resistance between the semiconductor layer and the Schottky electrode, the generation of the Si nodule must be suppressed.

The object of this specification is to provide a semiconductor device having a Schottky electrode capable of suppressing the generation of Si nodules.

One embodiment of a semiconductor device disclosed in this specification comprises a semiconductor layer including Si, and a Schottky electrode being in Schottky contact with at least a part of one of main surfaces of the semiconductor layer. A material of the Schottky electrode is an Al—Si alloy including at least one metal selected from the group consisting of Ti, Ta, Nb, Hf, Zr, W, Mo and V.

A transition metal of Ti, Ta, Nb, Hf, Zr, W, Mo, or V, when used as an additive to the Al—Si alloy, has an effect of suppressing diffusion of Al included in the Al—Si alloy. The Schottky electrode of the semiconductor device of the above embodiment, which includes at least one of these transition metals, suppresses the diffusion of Al included in the Al—Si alloy to the interface between the semiconductor layer and the Schottky electrode. As a result, segregation of Si is suppressed and the generation of Si nodules is suppressed.

### BRIEF DESCRIPTION OF DRAWINGS

FIG. 1 shows schematically a cross-sectional view of a main part of a semiconductor device of a first embodiment.

FIG. 2 shows reverse leakage current characteristics of the semiconductor device of the first embodiment.

FIG. 3 shows schematically a cross-sectional view of a main part of the semiconductor device of a second embodiment.

### DETAILED DESCRIPTION OF INVENTION

### First Embodiment

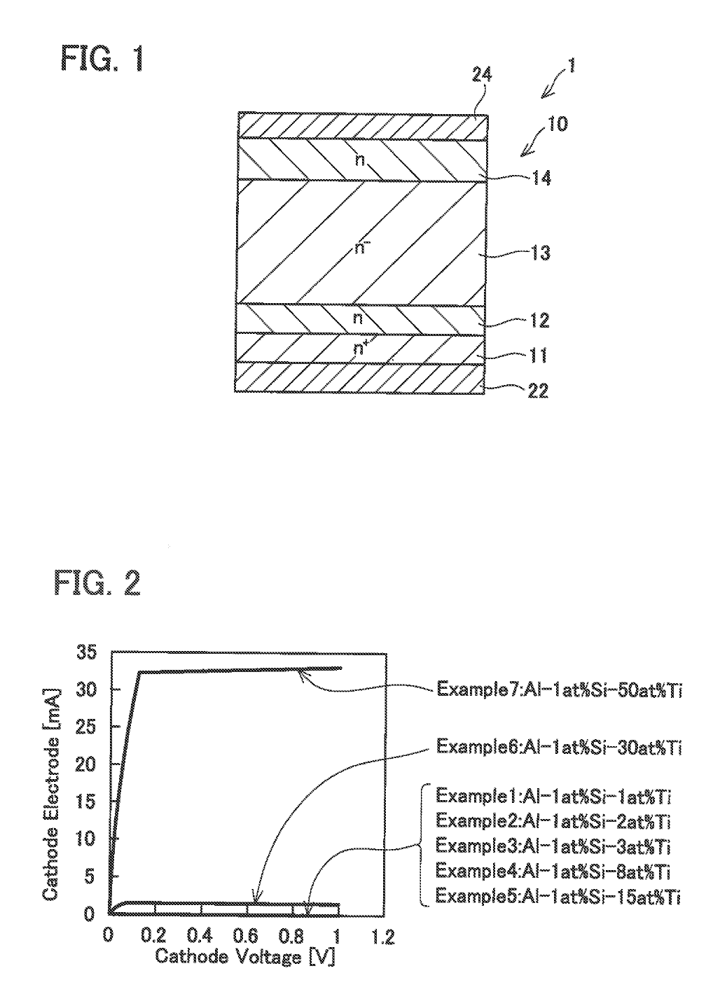

As shown in FIG. 1, a semiconductor device 1 is such kind of semiconductor device that is called a Schottky diode and includes a silicon single-crystal semiconductor layer 10, a cathode electrode 22 coating a bottom surface of the semiconductor layer 10, and an anode electrode 24 coating a top surface of the semiconductor layer 10.

The semiconductor layer 10 has an n⁺ type cathode region 11, an n type buffer region 12, an n⁻ type drift region 13, and an n type bather region 14.

The cathode region 11 is disposed in a lower layer part of the semiconductor layer 10 and is exposed at the bottom surface of the semiconductor layer 10. The cathode region 11 is formed by introducing phosphorus into the bottom surface of the semiconductor layer 10, using an ion implantation technology. The impurity concentration of the cathode region 11 is approximately 1×10¹⁷ to 5×10²⁰ cm⁻³.

The buffer region 12 is disposed in a lower layer part of the semiconductor layer 10 and is arranged between the cathode region 11 and the drift region 13. The buffer region 12 is formed by introducing phosphorus into the bottom surface of the semiconductor layer 10, using the ion implantation technology. The impurity concentration of the buffer region 12 is approximately 1×10¹⁶ to 1×10¹⁹ cm⁻³.

The drift region 13 is arranged between the buffer region 12 and the barrier region 14. The drift region 13 is the remainder of the semiconductor layer 10 after the cathode region 11, the buffer region 12, and the barrier region 14 are formed therein. The impurity concentration of the drift region 13 is approximately 1×10¹² to 1×10¹⁵ cm⁻³.

The barrier region 14 is arranged in an upper layer part of the semiconductor layer 10 and is exposed at the top surface of the semiconductor layer 10. The barrier region 14 is formed by introducing phosphorus into the top surface of the semiconductor layer 10, using the ion implantation technology. The impurity concentration of the bather region 14 is approximately 1×10¹⁵ to 1×10¹⁸ cm⁻³. The thickness of the barrier region 14 is approximately 0.5 to 3.0 μm.

The cathode electrode 22 is composed of a two-layer film of a Ti layer and an Al—Si alloy layer and the Ti layer is in contact with the cathode region 11. The film thickness of the Ti layer is approximately 30 nm and the film thickness of the Al—Si alloy layer is approximately 1 μm. An atomic concentration of Si (hereafter may be denoted as ‘Si atomic concentration’) in the Al—Si alloy is approximately 1 at % (atomic percent). The cathode electrode 22 is in ohmic contact with the cathode region 11 via the Ti layer. The cathode electrode 22 is formed by laminating the Ti layer and the Al—Si alloy layer in sequence on the bottom surface of the semiconductor layer 10, using a vapor deposition technology.

The anode electrode 24 is composed of a single-layer film of the Al—Si alloy layer including Ti. The film thickness of the anode electrode 24 is approximately 1 μm. The Si atomic concentration of the anode electrode 24 is approximately 1 at % and the atomic concentration of Ti (hereafter may be denoted as ‘Ti atomic concentration’) therein is 1 to 50 at % (details will be described later). The anode electrode 24 is in Schottky contact with the barrier region 14. The anode electrode 24 is formed on the top surface of the semiconductor layer 10, using the vapor deposition technology. After the formation of the cathode electrode 22 on the bottom surface of the semiconductor layer 10 and the formation of the anode electrode 24 on the top surface of the semiconductor layer 10, a heat treatment of 500° C. in a reducing atmosphere is applied to decrease the interface resistance and obtain a reliable electric contact.

Using a SEM (scanning electron microscope), how the Si nodule was generated in the examples and a comparative example was observed. Semiconductor devices having the anode electrodes 24 with the Ti atomic concentrations of 1, 2, 3, 8, 15, 30, and 50 at % were prepared as the examples. A semiconductor device having the anode electrode 24 not including Ti was prepared as the comparative example.

As shown in the following table, each of the semiconductor devices of the examples, as compared with the comparative example, had reduced the generation of the Si nodule. In particular, in the semiconductor devices having the anode electrodes with the Ti atomic concentration of 3, 8, 15, 30, and 50 at %, no Si nodule was observed. The reason is considered to be that diffusion of Al included in the anode electrode 24 was suppressed by Ti and the segregation of Si within the Al—Si alloy layer was suppressed in the interface between the anode electrode 24 and the barrier region 14.

| | Anode Electrode Composition | Nodule Generation |
|---|---|---|
| | (at %) | Evaluation |
| Example 1 | Al—1 at % Si—1 at % Ti | A few |
| Example 2 | Al—1 at % Si—2 at % Ti | A few |
| Example 3 | Al—1 at % Si—3 at % Ti | None |
| Example 4 | Al—1 at % Si—8 at % Ti | None |
| Example 5 | Al—1 at % Si—15 at % Ti | None |
| Example 6 | Al—1 at % Si—30 at % Ti | None |
| Example 7 | Al—1 at % Si—50 at % Ti | None |
| Comparative | Al—1 at % Si | Many |
| Example | | |

FIG. 2 shows reverse bias characteristics of the semiconductor device 1. It has been confirmed that each of the semiconductor devices having the anode electrodes 24 with the Ti atomic concentration of 1, 2, 3, 8, 15, and 30 at % have good diode characteristics with small reverse leakage current. The reason is considered to be that, when the Ti atomic concentration is 30 at % or less, the barrier height (φB) between the barrier region 14 and the anode electrode 24 is controlled so as to be 0.6 to 0.8 eV as an intermediate value of the barrier heights of the Al—Si alloy (φB=0.8 eV) and Ti (φB=0.55 eV). On the other hand, the semiconductor device having the anode electrode 24 with the Si atomic concentration of 50 at % has a large reverse leakage current. The reason is considered to be that Ti included in the anode electrode 24 was segregated at the interface between the barrier region 14 and the anode electrode 24, which caused the barrier height (φB) between the barrier region 14 and the anode electrode 24 to become 0.55 eV, which is the barrier height of Ti.

Thus, since the semiconductor device 1 having the anode electrode 24 including Ti can have the generation of the Si nodule suppressed, the interface resistance between the semiconductor layer 10 and the anode electrode 24 is lowered and a good electrical contact is obtained. In particular, when the Ti atomic concentration of the anode electrode 24 is 3 at % or more, the Si nodule is prevented from being generated at the interface between the semiconductor layer 10 and the anode electrode 24, resulting in stable electric characteristics of the semiconductor device 1 and enhanced reliability of the semiconductor device 1. Further, with the Ti atomic concentration of the anode electrode 24 at 30 at % or less, the reverse leakage current is suppressed since the barrier height of the interface between the semiconductor layer 10 and the anode electrode 24 is maintained at an appropriate height. In particular, with the Ti atomic concentration of the anode electrode 24 at 15 at % or less, the reverse leakage current is prevented. Thus, in the semiconductor device 1 having the anode electrode 24 including Ti, if the Ti atomic concentration is 3 to 30 at %, more preferably 3 to 15 at %, the suppression of the Si nodule generation and the suppression of the reverse leakage current can both be achieved.

### Second Embodiment

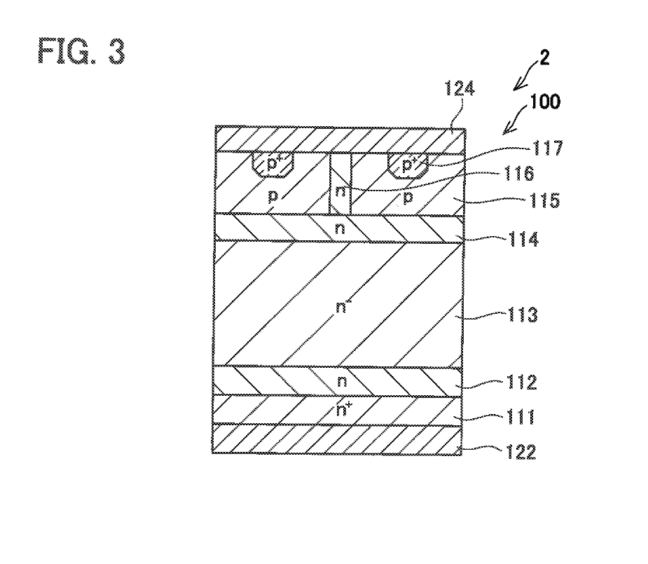

As shown in FIG. 3, a semiconductor device 2 is a semiconductor device having a diode structure with enhanced reverse recovery characteristics and has a silicon single-crystal semiconductor layer 100, a cathode electrode 122 coating a bottom surface of the semiconductor layer 100, and an anode electrode 124 coating a top surface of the semiconductor layer 100.

The semiconductor layer 100 has an n⁺ type cathode region 111, an n type buffer region 112, an n⁻ type drift region 113, and an n type bather region 114, a p type anode region 115, an n type pillar region 116, and p⁺ type contact regions 117.

The cathode region 111 is disposed in a lower layer part of the semiconductor layer 100 and is exposed at the bottom surface of the semiconductor layer 100. The cathode region 111 is formed by introducing phosphorus into the bottom surface of the semiconductor layer 100, using the ion implantation technology. The impurity concentration of the cathode region 111 is approximately 1×10¹⁷ to 5×10²⁰ cm⁻³.

The buffer region 112 is disposed in a lower layer part of the semiconductor layer 100 and is arranged between the cathode region 111 and the drift region 113. The buffer region 112 is formed by introducing phosphorus into the bottom surface of the semiconductor layer 100, using the ion implantation technology. The impurity concentration of the buffer region 112 is approximately 1×10¹⁶ to 1×10¹⁹ cm⁻³.

The drift region 113 is arranged between the buffer region 112 and the barrier region 114. The drift region 13 is the remainder of the semiconductor layer 100 after the cathode region 111, the buffer region 112, the barrier region 114, the anode region 115, the pillar region 116, and the contact regions 117 are formed therein. The impurity concentration of the drift region 113 is approximately 1×10¹² to 1×10¹⁵ cm⁻³.

The barrier region 114 is arranged in an upper layer part of the semiconductor layer 100 and is arranged between the drift region 113 and the anode region 115. The barrier region 114 is formed by introducing phosphorus into the top surface of the semiconductor layer 100, using the ion implantation technology. The impurity concentration of the barrier region 114 is approximately 1×10¹⁵ to 1×10¹⁸ cm⁻³. The thickness of the barrier region 114 is approximately 0.5 to 3.0 μm.

The anode region 115 is arranged in an upper layer part of the semiconductor layer 100 and is exposed at the top surface of the semiconductor layer 100. The anode region 115 is formed by introducing boron into the top surface of the semiconductor layer 100, using the ion implantation technology. The impurity concentration of the anode region 115 is approximately 1×10¹⁶ to 1×10¹⁹ cm⁻³.

The pillar region 116 is arranged in an upper layer part of the semiconductor layer 100 and is arranged to penetrate through the anode region 115. The pillar region 116 has one edge thereof in contact with the barrier region 114 and has the other edge thereof exposed at the top surface of the semiconductor layer 100. The pillar region 116 exposed at the top surface of the semiconductor layer 100 has a rectangular shape and has an area of 20 μm×20 μm. The pillar region 116 is formed by introducing phosphorus into the top surface of the semiconductor layer 100, using the ion implantation technology. The impurity concentration of the pillar region 116 is approximately 1×10¹⁶ to 1×10¹⁹ cm⁻³.

The contact regions 117 are arranged in an upper layer part of the semiconductor layer 100, are surrounded by the anode region 115, and are exposed at the top surface of the semiconductor layer 100. The contact regions 117 are formed by introducing boron into the top surface of the semiconductor layer 100, using the ion implantation technology. The impurity concentration of the contact regions 117 is approximately 1×10¹⁷ to 1×10²⁰ cm⁻³.

The cathode electrode 122 is composed of a two-layer film of a Ti layer and an Al—Si alloy layer, and the Ti layer is in contact with the cathode region 111. The film thickness of the Ti layer is approximately 30 nm and the film thickness of the Al—Si alloy layer is approximately 1 μm. Si atomic concentration of the Al—Si alloy is approximately 1 at %. The cathode electrode 122 is in ohmic contact with the cathode region 111 via the Ti layer. The cathode electrode 122 is formed by laminating the Ti layer and the Al—Si alloy layer in sequence on the bottom surface of the semiconductor layer 100, using the vapor deposition technology.

The anode electrode 124 is composed of a single-layer film of the Al—Si alloy layer including Ti. The film thickness of the anode electrode 124 is approximately 1 μm. The Si atomic concentration of the anode electrode 124 is approximately 1 at % and the Ti atomic concentration thereof is approximately 8 at %. The anode electrode 124 is in ohmic contact with the anode region 115 and the contact region 117. The anode electrode 124 is in Schottky contact with the pillar region 116. The barrier height (φB) between the pillar region 116 and the anode electrode 124 is approximately 0.75 eV. The anode electrode 124 is formed on the top surface of the semiconductor layer 100, using the vapor deposition technology. After the formation of the cathode electrode 122 on the bottom surface of the semiconductor layer 100 and the formation of the anode electrode 124 on the top surface of the semiconductor layer 100, a heat treatment of 500° C. in a reducing atmosphere is applied to decrease the interface resistance and obtain a reliable electric contact.

Features will be described hereinbelow of the semiconductor device 2. When a forward bias is applied between the cathode electrode 122 and the anode electrode 124, the anode electrode 124 and the pillar region 116 are short-circuited by way of a Schottky interface. Since the pillar region 116 and the barrier region 114 are of almost the same potential, a difference in potential between the barrier region 114 and the anode electrode 124 becomes almost equal to a voltage drop at the Schottky interface. Since the voltage drop at the Schottky interface is sufficiently smaller than a built-in voltage of a pn junction between the anode region 115 and the barrier region 114, the injection of holes from the contact region 117 and the anode region 115 to the drift region 113 is suppressed. A forward current flows between the anode electrode 124 and the cathode electrode 122 mainly via the Schottky interface between the anode electrode 124 and the pillar region 116, the pillar region 116, the barrier region 114, the drift region 113, the buffer region 112, and the cathode region 111. When the voltage between the anode electrode 124 and the cathode electrode 122 is switched from the forward bias to the reverse bias, a reverse current is limited by the Schottky interface between the anode electrode 124 and the pillar region 116.

As described above, in the semiconductor device 2 of this embodiment, since the injection of the holes from the contact region 117 and the anode region 115 to the drift region 113 is suppressed when the forward bias is applied, reverse recovery current is small and reverse recovery time is short. According to the semiconductor device 2 of this embodiment, a switching loss can be minimized without performing lifetime control of the drift region 113.

In the semiconductor device 2, since a contact area of the anode electrode 124 and the pillar region 116 is small, it is especially important to suppress the generation of the Si nodule at the interface between the anode electrode 124 and the pillar region 116 for realizing a good electric contact. Since the anode electrode 124 of the semiconductor device 2 includes Ti, the diffusion of Al included in the anode electrode 124 is suppressed by Ti. This suppresses the diffusion of Al included in the anode electrode 124 to the interface between the anode electrode 124 and the pillar region 116 such that the segregation of Si within the Al—Si alloy layer can be suppressed and the generation of the Si nodule can accordingly be suppressed at the interface between the anode electrode 124 and the pillar region 116.

While, in each of the above embodiments, the anode electrode 24 or 124 was of a single layer of the Al—Si alloy including Ti, even the anode electrode 24 or 124 of multiple layers can also suppress the generation of the Si nodule so long as the part in contact with the semiconductor layer 10 or 100 is the Al—Si alloy layer including Ti. For example, the anode electrodes 24 and 124 may be of multiple layers of an Al—Si alloy layer including Ti and an Al—Si alloy layer not including Ti. In such a case, it is desirable for the Al—Si alloy layer including Ti to have the film thickness of at least 20 nm or more. For enhanced heat-resistant characteristics, it is desirable that the film thickness of the anode electrodes 24 and 124 be thick and for a solder joint, a metal film of Ni, Au, etc., may be layered over the Al—Si alloy film.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

Some of the technical features disclosed in this specification are summarized below. Note that matters described below respectively independently have technical utility.

One embodiment of a semiconductor device disclosed in this specification may comprise a semiconductor layer including Si, and a Schottky electrode being in Schottky contact with at least a part of one of main surfaces of the semiconductor layer. Here, the semiconductor layer including Si is a semiconductor including at least Si as a constituent element, and generally be Si or SiC. A material of the Schottky electrode may be an Al—Si alloy including at least one metal selected from the group consisting of Ti, Ta, Nb, Hf, Zr, W, Mo and V. An atomic concentration of Si in the Al—Si alloy of the Schottky electrode is not limited to a specific one as long as it includes as least Si. The atomic concentration of Si in the Al—Si alloy of the Schottky electrode is generally 0.1 to 1.0 at % (atomic percent). The semiconductor device is configured to demonstrate a specific function by using a barrier height between the semiconductor layer and the Schottky electrode. In one example, the semiconductor device is a Schottky diode, and demonstrates a rectification by using the barrier height between the semiconductor layer and the Schottky electrode. Since the Schottky electrode of this embodiment is made of the Al—Si alloy, the diffusion of Al included in the Schottky electrode to the semiconductor layer is suppressed and the generation of an aluminum spike is suppressed. Further, since the Schottky electrode of this embodiment includes at least one of transition metals of Ti, Ta, Nb, Hf, Zr, W, Mo, or V, the diffusion of Al included in the Al—Si alloy to an interface between the semiconductor layer and the Schottky electrode is suppressed such that the segregation of Si in the Al—Si alloy is suppressed and the generation of Si nodule is thereby suppressed.

The semiconductor device of the above embodiment may further comprise a cathode electrode being in contact with the other one of the main surfaces of the semiconductor layer. In this case, the semiconductor layer may include a cathode region of a first conductivity type, a drift region of the first conductivity type, a barrier region of the first conductivity type, an anode region of a second conductivity type and a pillar region of the first conductivity type. The cathode region may be in contact with the cathode electrode. The drift region may be disposed above the cathode region, wherein an impurity concentration of the drift region may be lower than an impurity concentration of the cathode region. The bather region may be disposed above the drift region, wherein an impurity concentration of the barrier region may be higher than an impurity concentration of the drift region. The anode region may be disposed above the barrier region. The pillar region may penetrate through the anode region, wherein one edge of the pillar region may be in contact with the barrier region and another one edge of the pillar region may be in Schottky contact with the Schottky electrode. Note that another semiconductor region may be disposed between the semiconductor regions mentioned above if necessary. This semiconductor device is a diode including the pillar region, and may be configured as a discrete or may be configured as a reverse conducting IGBT in which an IGBT is integrated in a same substrate. In this semiconductor device, a contact area between the Schottky electrode and the pillar region is small. Therefore, it is very important to suppress the generation of Si nodule at the interface between the Schottky electrode and the pillar region for realizing a good electrical contact. By applying the Schottky electrode disclosed in this specification to such a semiconductor device, electrical properties of the semiconductor device become stable and a reliability of the semiconductor device is improved.

In the semiconductor device of the above embodiment, a contact area between the pillar region and the Schottky electrode may be equal to or less than 400 μm². In a case where the contact area between the pillar region and the Schottky electrode is thus small, the Schottky electrode in which the generation of Si nodule is suppressed is especially advantageous.

In the semiconductor device of the above embodiment, an atomic concentration of Ti in the Schottky electrode may be equal to or more than 3 at %. When the atomic concentration of Ti in the Schottky electrode is equal to or more than 3 at %, the generation of Si nodule can be prevented.

In the semiconductor device of the above embodiment, the atomic concentration of Ti in the Schottky electrode may be equal to or less than 30 at %, more preferably equal to or less than 15 at %. When the atomic concentration of Ti in the Schottky electrode is equal to or less than 30 at %, a reverse leakage current can remarkably be suppressed. When the atomic concentration of Ti in the Schottky electrode is equal to or less than 15 at %, the reverse leakage current can be prevented.

In the semiconductor device of the above embodiment, a barrier height between the Schottky electrode and the semiconductor layer may be 0.6 to 0.9 eV. When the barrier height is formed within this range, the reverse leakage current at the Schottky electrode can be suppressed. The barrier height between the Schottky electrode and the semiconductor layer may be more preferably 0.7 to 0.8 eV.

What is claimed is:

1. A semiconductor device comprising:
a semiconductor layer including Si; and
a Schottky electrode being in Schottky contact with at least a part of one of main surfaces of the semiconductor layer, wherein
a material of the Schottky electrode is an Al—Si alloy including at least one metal selected from the group consisting of Ti, Ta, Nb, Hf, Zr, W, Mo and V.

2. The semiconductor device according to claim 1, further comprising:
a cathode electrode being in contact with the other of the main surfaces of the semiconductor layer, wherein
the semiconductor layer includes:
a cathode region of a first conductivity type being in contact with the cathode electrode;
a drift region of the first conductivity type disposed above the cathode region, wherein an impurity concentration of the drift region is lower than an impurity concentration of the cathode region;
a barrier region of the first conductivity type disposed above the drift region, wherein an impurity concentration of the barrier region is higher than the impurity concentration of the drift region;
an anode region of a second conductivity type disposed above the barrier region, and
a pillar region of the first conductivity type penetrating through the anode region, wherein one edge of the pillar region is in contact with the barrier region and another one edge of the pillar region is in Schottky contact with the Schottky electrode.

3. The semiconductor device according to claim 2, wherein
a contact area between the pillar region and the Schottky electrode is equal to or less than 400 μm².

4. The semiconductor device according to claim 1, wherein
an atomic concentration of Ti in the Schottky electrode is equal to or more than 3 at %.

5. The semiconductor device according to claim 1, wherein
an atomic concentration of Ti in the Schottky electrode is equal to or less than 30 at %.

6. The semiconductor device according to claim 5, wherein
the atomic concentration of Ti in the Schottky electrode is equal to or less than 15 at %.

7. The semiconductor device according to claim 1, wherein
a barrier height between the Schottky electrode and the semiconductor layer is 0.6 to 0.9 eV.
